(19) United States
(12) Patent Application Publication
(10) Pub. No.: US 2014/0029170 A1
(43) Pub. Date: Jan. 30, 2014

(54) Front Frame, Method for Making The Same, and Liquid Crystal Display Device

(71) Applicants: Yu-chun Hsiao, Shenzhen (CN); Yue Wu, Shenzhen (CN)

(72) Inventors: Yu-chun Hsiao, Shenzhen (CN); Yue Wu, Shenzhen (CN)

(73) Assignee: SHENZHEN CHINA STAR OPTOELECTRONICS TECHNOLOGY CO. LTD., Shenzhen (CN)

(21) Appl. No.: 13/581,304

(22) PCT Filed: Jul. 26, 2012
(86) PCT No.: PCT/CN12/79175

§ 371 Date: Aug. 25, 2012

(30) Foreign Application Priority Data
Jul. 24, 2012 (CN) 201210257671.7

(51) Int. Cl. H05K 7/18; B21D 53/74; H05K 7/02

(52) U.S. Cl. 361/679.01; 72/324; 312/7.2

(57) ABSTRACT

The present invention discloses a front frame, a method for making the front frame, and a liquid crystal display device incorporated with the front frame. The method includes the steps of a) providing, an elongate metallic strip having head and tail and divided by cutting three predetermined V-cuts to divide into four interconnected sections; b) conducting a rolling process along a central line of the metallic strip such that an angled strip having a top surface and a skirt perpendicular the top surface is formed, wherein the V-cuts are located on the top surface; c) folding the angled strip centered on each of the V-cuts ninety (90) degrees such that each individual section is perpendicular to each other so as to configure a rectangular frame; and d) interconnecting the head and the tail of the angled strip to configure a rigid front frame. The metallic strip is transformed into an angled strip angled strip by means of rolling, and then folded, interconnected so as to configure the front frame. The front frame made through conventional pressing can be readily replaced. The operation is simplified, and is readily suitable for making front frame with larger dimensions.

The present invention relates to a technical field of liquid crystal display, and more particularly to a front frame, a method for making the same, and a liquid crystal display device.

Currently, a liquid crystal display (LCD) or LCD incorporated with LED light source is configured with a front frame which is integrally formed by pressing with a sheet metal, or alternatively, the front frame can be formed by individual piece, and then interconnected together. However, while the dimension of the LCD becomes larger and larger, the pressing mold for manufacturing conventional front frame has to become more and more larger so as to meet the requirement. It is inevitably that the larger the mold, the higher the cost. For those assembled front frame, there is at least two welding process has to be conducted, and this again increase the cost.

Accordingly, there is a requirement and necessity to provide a front frame and a method for making it, as well as a liquid crystal display device configured with such a front frame.

### SUMMARY OF THE INVENTION

It is the object of the present invention to provide a front frame, a method for making the same, and a liquid crystal display device so as to reduce the manufacturing cost of the front frame.

In order to resolve the technical issue encountered by the prior art, the present invention introduce a technical solution by providing a method for making a front frame, including the steps of a) providing an elongate metallic strip having head and tail and divided by cutting three predetermined V-cuts to divide into four interconnected sections; b) conducting a rolling process along a central line of the metallic strip such that an angled strip having a top surface and a skirt perpendicular the top surface is formed, wherein the V-cuts are located on the top surface; c) folding the angled strip centered on each of the V-cuts ninety (90) degrees such that each individual section is perpendicular to each other so as to configure a rectangular frame; and d) interconnecting the head and the tail of the angled strip to configure a rigid front frame.

Wherein further comprises the step of e) forming a first chamfered lead-in on the bead of the top surface, and a second chamfered lead-in on the tail of the top surface, wherein the first and second chamfered lead-ins are shaped to be interconnected together.

Wherein the metallic strip is ferric sheet, and the V-cuts, the first and second chamfered lead-ins are formed by stamping.

Wherein the head and tail are interconnected by means of laser welding, riveting and screwing.

Wherein the V-cut is an isosceles triangle, and the angle adjacent to the skirt is ninety (90) degrees.

In order to resolve the technical issue encountered by the prior art, the present invention introduce a technical solution by providing a front frame configured by folding consecutively sections of as metallic strip into as rectangular frame, wherein the metallic strip is transformed into an angled strip having a top surface and a skirt by way of rolling, wherein the top surface is defined at least three V-cuts between a head and a tail of the metallic strip. Wherein the metallic strip is divided into four interconnected sections and then folded centered on a dividing line of the V-cut such that every two adjacent sections are perpendicular to each other to configure the front frame with four sections.

Wherein further comprises the step of e) forming a first chamfered lead-in on the head of the top surface, and a second chamfered lead-in on the tail of the top surface, wherein the first and second chamfered lead-ins are shaped to be interconnected together.

Wherein the V-cut is an isosceles triangle, and the angle adjacent to the skirt is ninety (90) degrees.

Wherein the head and tail are interconnected by means of laser welding, riveting and screwing.

In order to resolve the technical issue encountered by the prior art, the present invention introduce a technical solution by providing a liquid crystal display device which incorporates a front frame configured by folding consecutively sections of a metallic strip into a rectangular frame, Wherein the metallic strip is transformed into an angled strip having a top surface and a skirt by way of rolling, wherein the top surface is defined at least three V-cuts between a head and a tail of the metallic strip. Wherein the metallic strip is divided into four interconnected sections and then folded centered on a dividing line of the V-cut such that every two adjacent sections are perpendicular to each other to configure the front frame with four sections.

Wherein further comprises the step of e) forming a first chamfered lead-in on the head of the top surface, and a second chamfered lead-in on the tail of the top surface, wherein the first and second chamfered lead-ins are shaped to be interconnected together.

Wherein the V-cut is an isosceles triangle, and the angle adjacent to the skirt is ninety (90) degrees.

Wherein the head and tail are interconnected by means of laser welding, riveting and screwing.

In conclusion, the metallic strip is transformed into an angled strip with a top surface and a skirt and further folded and interconnected to configure the rigid front frame. The present invention can readily replace the front frame made by pressing. The front frame made in accordance with the present invention features simplified manufacturing process, and with reduced cost. This is really beneficial to the front frame with enlarged dimensions.

Furthermore, the head and the tail of the metallic strip have to be permanently interconnected. As compared to the prior art, the number of the joint is reduced and the manufacturing process is simplified. The manufacturing cost is not doubt reduced.

### SUMMARY OF THE INVENTION

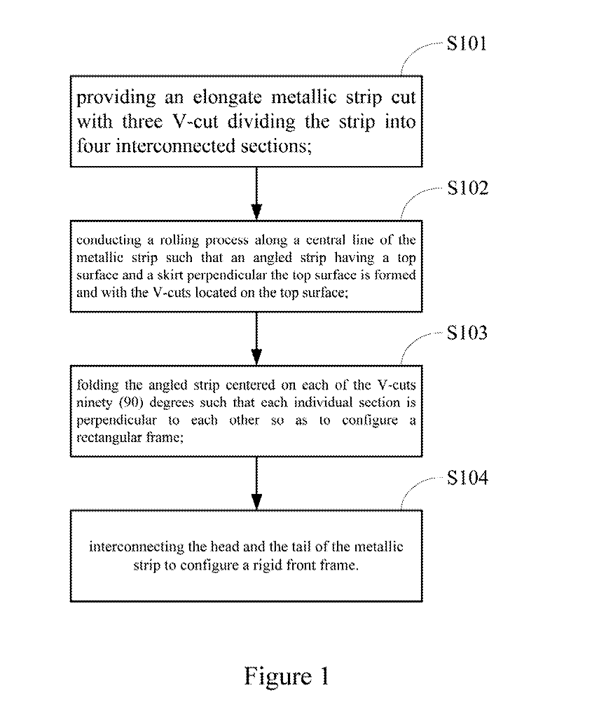

FIG. 1 is a flow diagram showing steps of a method for making a front frame in accordance with the present invention;

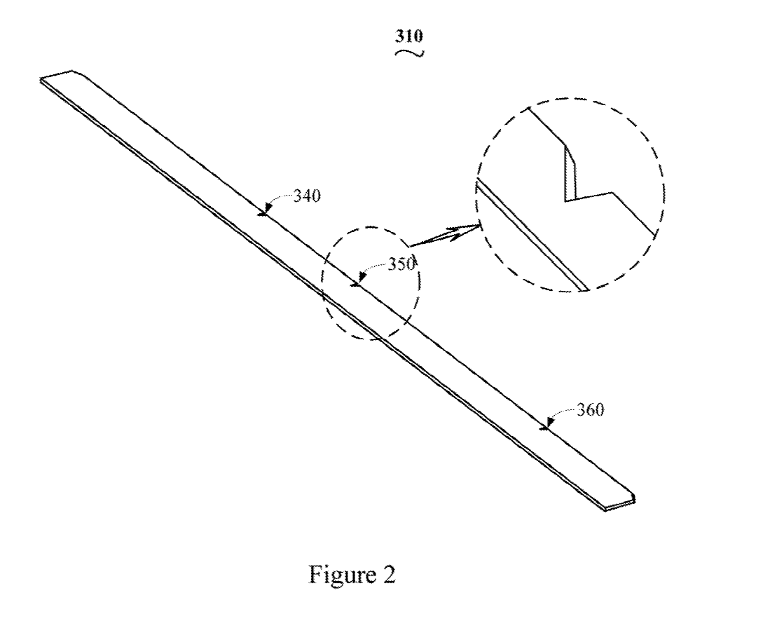

FIG. 2 is an illustrational and perspective view of a metallic strip made in accordance with the present invention before it is folded;

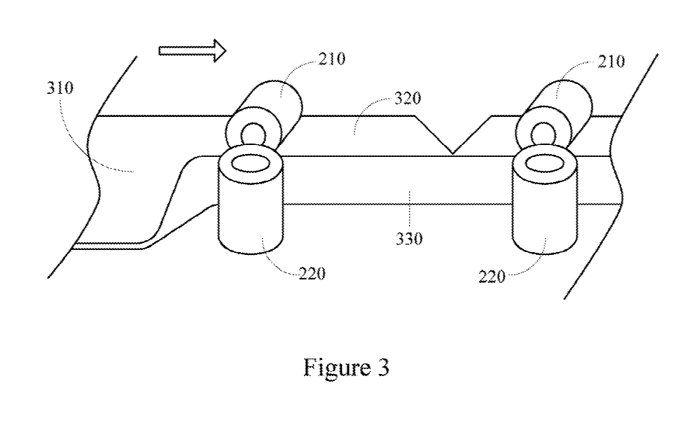

FIG. 3 is an illustrational view showing that the metallic strip is transferred into an angle strip by means of rollers;

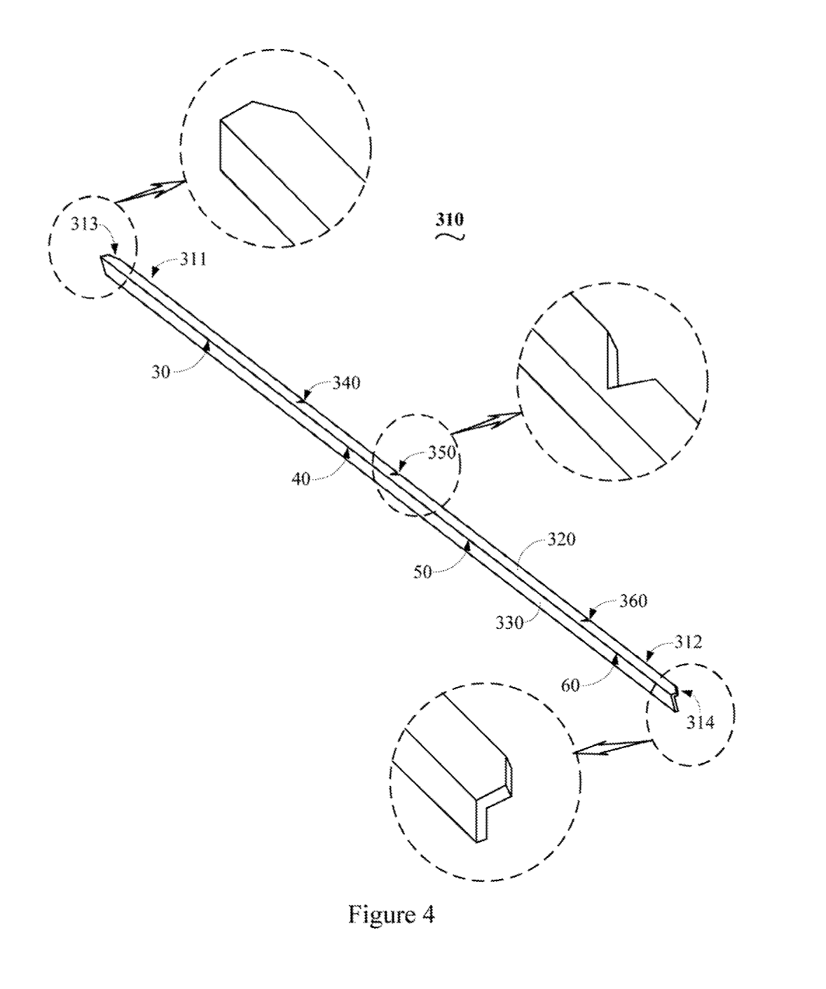

FIG. 4 is an illustration showing the metallic strip shown in FIG. 2 after it is folded into the angle strip;

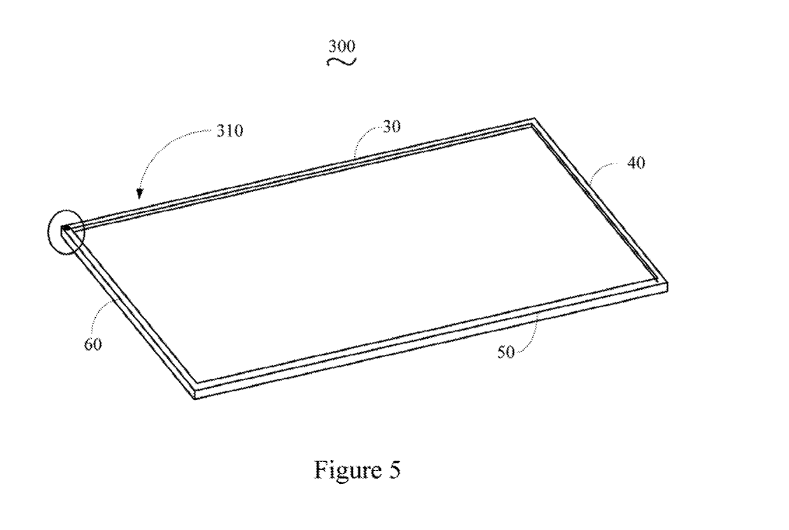

FIG. 5 is an illustrational, view of the front frame formed by folding the individual pieces shown in FIG. 3;

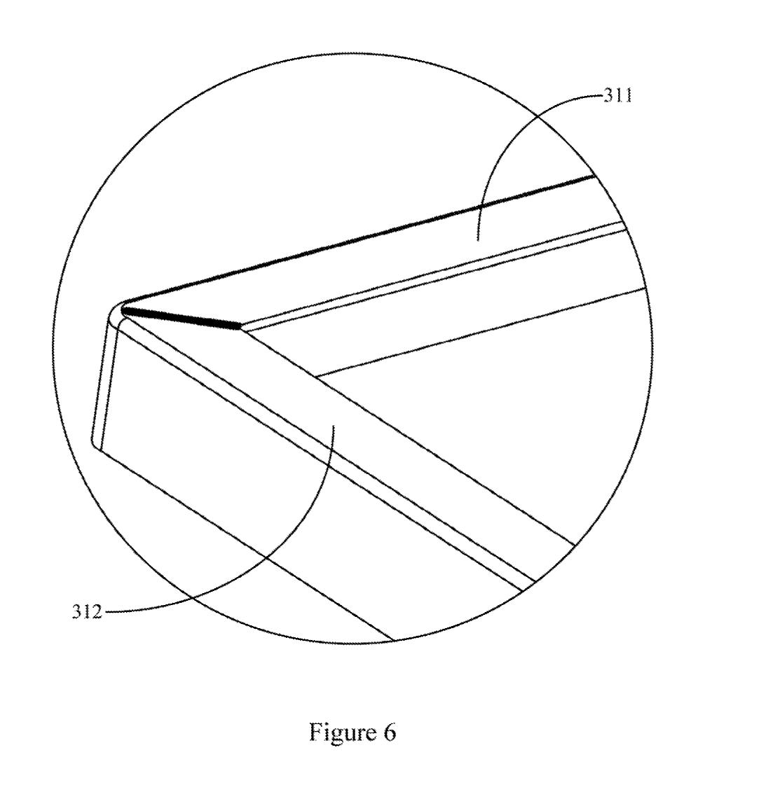

FIG. 6 is an illustrational view showing the individual pieces are interconnected with head-to-tail arrangement in accordance with a first embodiment of the present invention; and

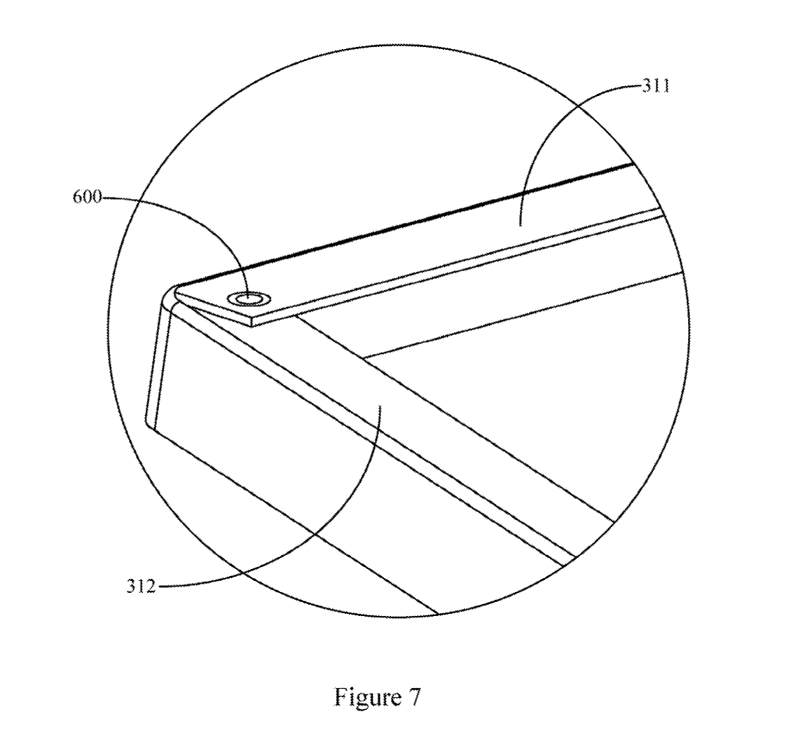

FIG. 7 is an illustrational view showing the individual pieces are interconnected with head-to-tail arrangement in accordance with a second embodiment of the present invention.

### DETAILED DESCRIPTION OF PREFERRED EMBODIMENT

Detailed description will be given in view of the preferred embodiments along with accompanied drawings.

FIG. 1 is a flow diagram showing steps of a method for making a front frame in accordance with the present invention. As shown in FIG. 1, the method for manufacturing the front frame includes the following steps.

Step S101: providing an elongate metallic strip cut with three V-cut dividing the strip into four interconnected sections;

In the current embodiment, as shown in FIG. 2, the metallic strip 310 is used to configure the front frame, wherein the length of the metallic strip 310 equals to the summary of four sides of the front frame.

FIG. 2 is an illustrational and perspective view of a front frame made in accordance with the present invention before it is folded. As shown in FIG. 2, the metallic strip 310 is an elongate metallic strip with three V-cuts 340, 350 and 360 which are defined with stamping along the metallic strip 310 with pre-determined length. The three V-cuts 340, 350 and 360 can readily divide the metallic strip 310 into four interconnected sections to properly configure a rectangular frame when folded.

In the current embodiment, the metallic strip 310 is made from a sheet metal cut into an elongate strip. In other embodiment, the metallic strip 310 can he made from other tensile and intensified material.

Step S102: conducting a rolling process along a central line of the metallic strip 310 such that an angle strip having a top surface and a skirt perpendicular the top surface is formed. Wherein the V-cuts 340, 350 and 360 are located on the top surface.

FIG. 3 is an illustrational view showing that the metallic strip is transferred into an angle strip by means of rollers. As shown in FIG. 3, the metallic strip 310 is fed into a roller machine and having the metallic strip 310 fed along a predetermined direction. The roller machine includes a horizontal roller 210 and a vertical roller 220 jointly transforming the metallic strip 310 into an angled strip having a skirt 330 created by the vertical roller 220. In the current embodiment, the depth of those three V-cuts 340, 350, and 360 are smaller or equal to the width of the top surface 320. After the metallic strip 310 is transformed into an angled strip, the top surface 320 and the skirt 330 are perpendicular to each other.

Step S103: folding the angled strip centered on each of the V-cuts ninety (90) degrees such that each individual section is perpendicular to each other so as to configure a rectangular frame,

FIG. 4 is an illustration showing the metallic strip 310 shown in FIG. 2 after it is folded into the angle strip. As shown in FIG. 4, the metallic strip includes a head 311, a tail 312, a top surface 320, a skirt 330, and three V-cuts 340, 350 and 360.

Wherein the top surface 320 and the skin 330 are perpendicular to each other. The top surface 320 and the skirt 330 are formed by rolling the metallic strip 310 into an angled strip. The V-cuts 340, 350 and 360 are arranged on the top surface and between the head 311 and the tail 312.

In the current embodiment, the V-cuts 240, 350 and 360 are an isosceles triangle with its bottom angle located adjacent to the skirt 330 and has a ninety (90) degrees. The V-cuts 340, 350 and 360 divide the metallic strip 310 into four sections 30, 40, 50 and 60.

FIG. 5 is an illustrational view of the front frame formed by folding the individual pieces shown in FIG. 3. As shown in FIG. 5, the front frame 300 is configured by folding the metallic strip 310. Substantially:

The front frame 300 is folded from the metallic strip 310 as centering on a central line dividing equally the V-cuts 340, 350 and 360. Once the metallic strip 310 is folded, every two adjacent sections 30, 40, 50 and 61) are perpendicular each other. Eventually, a rectangular frame is configured.

In the current embodiment, the depth of the V-cuts 340, 350 and 360 equals to the width of the top surface 320, and the V-cuts 340, 350 and 360 are isosceles triangles. When the metallic strip 310 is folded, it is folded centered on a central line equally dividing the V-cuts 340, 350 and 360. Once the metallic strip 310 is folded, every two adjacent sections 30, 40, 50 and 60 are perpendicular each other. In addition, the head 311 and the tail 312 are each provided with a chamfered lead-in and once the head 311 and the tail 312 are coupled, a seamless joint can be created.

In other embodiments. the V-cuts 340, 350 and 360 can be selected from other suitable angles. If the angle of the V-cuts 340, 350 and 360 is less than ninety (90) degrees, then the overlapped portions of each of the V-cuts 340, 350 and 360 can he further welded with laser, or riveting, or screwing, creating a seamless joint over the top surface 320. If the angle of the V-cuts 340, 350 and 360 is larger than ninety (90) degrees, again, a gap between two adjacent sides of each of the V-cuts 340, 350, and 360) can be further touched up with laser so as to provide a seamless joint across the top surface 320 of the front frame 300.

Step S104: interconnecting the head 311 and the tail 312 of the metallic strip to configure rigid front frame 300.

In the current embodiment, the metallic strip 310 shown in FIG. 4 further includes a first lead-in 313, and a second lead-in 314. The first lead-in 313 is located at the first section 30, and on the head 311 of the top surface 320 of the metallic strip 310. The second lead-in 314 is located at the first section 60, and on the tail 312 of the top surface 320 of the metallic strip 310. The first and second lead-ins 313, 314 are dimensioned such that the head 311 and the tail 312 can be readily interconnected. It should he noted that the first and second lead-ins 313, 314 are formed by stamping.

The head 311 and tail 312 of the front frame 300 of FIG. 5 are interconnected by means of laser welding (FIG. 6), or by riveting or screwing. As shown in FIG. 7, when the head 311 and the tail 312 are interconnected with rivets or screws, the head 311 and tail 312 are each provided with openings 600 to facilitating the riveting and screwing, and bolting. As a result, the head 311 and the tail 312 can be readily and securely interconnected.

In addition, it should be noted that there is other embodiments, such as:

In another embodiment, the head 311 and the tail 312 of the metallic strip 310 have not been provided with the first and second lead-ins 313 and 314. Still, the head 311 and the tail 312 can be securely interconnected by laser welding, riveting or screwing. Again, when the head 311 and the tail 312 are interconnected with rivets or screws, the head 311 and tail 312 are each provided with openings 600 to facilitating the riveting and screwing, and bolting. As a result, the head 311 and the tail 312 can he readily and securely interconnected.

The present invention further provides a liquid crystal display device incorporated with the front frame disclosed above. Since the working principle and configuration of the liquid crystal display device is known to the skilled in the art, and as a result, no detailed description is given therebelow.

In conclusion, the metallic strip is transformed into an angled strip with a top surface and a skirt and further folded and interconnected to configure the rigid front frame. The present invention can readily replace the front frame made by pressing. The front frame made in accordance with the present invention features simplified manufacturing process, and with reduced cost. This is really beneficial to the front frame with enlarged dimensions.

Furthermore, the head and the tail of the metallic strip have to be permanently interconnected. As compared to the prior art, the number of the joint is reduced and the manufacturing process is simplified. The manufacturing cost is not doubt reduced.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

1. A method fur making a front frame. including the steps of:
a) providing an elongate metallic strip having head and tail and divided by cutting three predetermined V-cuts to divide into four interconnected sections;
b) conducting a rolling process along a central line of the metallic strip such that an angled strip having a top surface and a skirt perpendicular the top surface is formed, wherein the V-cuts are located on the top surface;
c) folding the angled strip centered on each of the V-cuts ninety (90) degrees such that each individual section is perpendicular to each other so as to configure a rectangular frame; and
d) interconnecting the head and the tail of the angled strip to configure a rigid front frame.

2. The method as recited in claim 1, wherein further comprises the step of:
e) forming a first chamfered lead-in on the head of the top surface, and a second chamfered lead-in on the tail of the top surface, wherein the first and second chamfered lead-ins are shaped to be interconnected together.

3. The method as recited in claim 2, wherein the metallic strip is ferric sheet, and the V-cuts, the first and second chamfered lead-ins are formed by stamping.

4. The method as recited in claim 1, wherein the head and tail are interconnected by means of laser welding, riveting and screwing.

5. The method as recited in claim 1, wherein the V-cut is an isosceles triangle, and the angle adjacent to the skirt is ninety (90) degrees.

6. A front frame configured by folding consecutively sections of a metallic strip into a rectangular frame, wherein the metallic strip is transformed into an angled strip having a top surface and a skirt by way of rolling, wherein the top surface is defined at least three V-cuts between a head and a tail of the metallic strip;
Wherein the metallic strip is divided into four interconnected sections and then folded centered on a dividing line of the V-cut such that every two adjacent sections are perpendicular to each other to configure the front frame with four sections.

7. The front frame as recited in claim 6, wherein a first chamfered lead-in is formed on the head of the top surface, and a second chamfered lead-in is formed on the tail of the top surface, wherein the first and second chamfered lead-ins are shaped to he interconnected together.

8. The front frame as recited in claim 6, wherein V-cut is an isosceles triangle, and the angle adjacent to the skirt is ninety (90) degrees.

9. The front frame as recited in claim 8, wherein the head and tail are interconnected by means of laser welding, riveting and screwing.

10. A liquid crystal display device including a front frame configured by folding consecutively sections of a metallic strip into a rectangular frame, wherein the metallic strip is transformed into an angled strip having a top surface and a skirt by way of rolling, wherein the top surface is defined at least three V-cuts between a head and a tail of the metallic strip;
Wherein the metallic strip is divided into four interconnected sections and then folded centered on a dividing line of the V-cut such that every two adjacent sections are perpendicular to each other to configure the front frame with four sections.

11. The liquid crystal display device as recited in claim 10, wherein a first chamfered lead-in is formed on the head of the top surface, and a second chamfered lead-in is formed on the tail of the top surface, wherein the first and second chamfered lead-ins are shaped to be interconnected together.

12. The liquid crystal display device as recited in claim 10, wherein the V-cut is an isosceles triangle, and the angle adjacent to the skirt is ninety (90) degrees.

13. The liquid crystal display device as recited in claim 13, wherein the head and tail are interconnected by means of laser welding, riveting and screwing.
